(19) United States
(12) Patent Application Publication
(10) Pub. No.: US 2026/0165190 A1
(43) Pub. Date: Jun. 11, 2026

(54) SEMICONDUCTOR PACKAGE

(71) Applicant: Samsung Electronics Co., Ltd., Suwon-si (KR)

(72) Inventors: Hyeonmin LEE, Suwon-si (KR); Gwangsik OH, Suwon-si (KR)

(73) Assignee: Samsung Electronics Co., Ltd., Suwon-si (KR)

(21) Appl. No.: 19/407,434

(22) Filed: Dec. 3, 2025

(30) Foreign Application Priority Data
Dec. 9, 2024 (KR) 10-2024-0181960

(51) Int. Cl. H01L 23/31; H01L 23/00; H01L 23/48; H01L 23/538; H01L 25/065

(52) U.S. Cl. CPC H10W 74/121; H10W 90/00; H10W 20/20; H10W 70/611; H10W 90/26; H10W 90/297; H10W 90/401; H10W 90/734; H10W 90/792

(57) ABSTRACT

A semiconductor package that includes a base chip; a plurality of first semiconductor chips sequentially stacked on the base chip in a vertical direction; a first molding member on the base chip, the first molding member surrounding side surfaces of the plurality of first semiconductor chips; an adhesive layer on an uppermost first semiconductor chip from among the plurality of first semiconductor chips; a dummy chip on the adhesive layer; and a second molding member on the first molding member, the second molding member surrounding respective side surfaces of the adhesive layer and the dummy chip.

### CROSS-REFERENCE TO RELATED APPLICATION

This application is based on and claims priority under 35 U.S.C. § 119 to Korean Patent Application No. 10-2024-0181960, filed on Dec. 9, 2024, in the Korean Intellectual Property Office, the disclosure of which is incorporated by reference herein in its entirety.

### BACKGROUND

The inventive concepts relate to semiconductor packages, and more particularly, to semiconductor packages including a plurality of semiconductor chips stacked in the vertical direction.

Recently, the demand for portable devices has rapidly increased in the electronics product market, and accordingly, the desire for miniaturized and lighter electronic components mounted in electronic products has increased. To these goals, there has been demand for semiconductor packages mounted in electronic components that process high-capacity data within a small volume and that have reduced and/or minimized defects. Semiconductor packages each having a plurality of semiconductor chips stacked in the vertical direction to reduce the size of the semiconductor package have been developed.

### SUMMARY

The inventive concepts provide a semiconductor package with improved reliability.

Advantages provided by the inventive concepts are not limited to advantages mentioned above, and other advantages may be clearly understood by those of ordinary skill in the art from the description below.

Some example embodiments of the inventive concepts provide a semiconductor package that includes a base chip; a plurality of first semiconductor chips sequentially stacked on the base chip in a vertical direction; a first molding member on the base chip, the first molding member surrounding side surfaces of the plurality of first semiconductor chips; an adhesive layer on an uppermost first semiconductor chip from among the plurality of first semiconductor chips; a dummy chip on the adhesive layer; and a second molding member on the first molding member, the second molding member surrounding respective side surfaces of the adhesive layer and the dummy chip.

Some example embodiments of the inventive concepts further provide semiconductor package that includes a first substrate; a base chip on the first substrate, the base chip including a base chip pad and a first dielectric layer on an upper surface of the base chip, and the first dielectric layer surrounding a side surface of the base chip pad; a plurality of first semiconductor chips stacked on the base chip, each first semiconductor chip from among the plurality of first semiconductor chips including a semiconductor chip pad and a second dielectric layer on a lower surface of the first semiconductor chip, and the second dielectric layer surrounding a side surface of the semiconductor chip pad; a first molding member on the base chip, the first molding member surrounding side surfaces of the plurality of first semiconductor chips; an adhesive layer on an uppermost first semiconductor chip from among the plurality of first semiconductor chips; a dummy chip on the adhesive layer; and a second molding member on the first molding member, the second molding member surrounding respective side surfaces of the adhesive layer and the dummy chip. An area on an upper surface of the first molding member, which does not overlap the dummy chip in a vertical direction, includes a modified area. The semiconductor chip pad on the lower surface of a lowermost first semiconductor chip from among the plurality of first semiconductor chips contacts the base chip pad in the vertical direction, and the first dielectric layer on the upper surface of the base chip contacts the second dielectric layer on the lower surface of the lowermost first semiconductor chip in the vertical direction.

Some example embodiments of the inventive concepts still further provide a semiconductor package including a first substrate; an external connection bump on a lower surface of the first substrate; a base chip on the first substrate, the base chip including a base chip pad and a first dielectric layer on an upper surface of the base chip, and the first dielectric layer surrounding a side surface of the base chip pad; a plurality of first semiconductor chips stacked on the base chip, each first semiconductor chip from among the plurality of first semiconductor chips including a semiconductor chip pad and a second dielectric layer on a lower surface of the first semiconductor chip, and the second dielectric layer surrounding a side surface of the semiconductor chip pad; a first molding member on the base chip, the first molding member surrounding side surfaces of the plurality of first semiconductor chips; an adhesive layer on an uppermost first semiconductor chip from among the plurality of first semiconductor chips; a dummy chip on the adhesive layer; and a second molding member on the first molding member, the second molding member surrounding respective side surfaces of the adhesive layer and the dummy chip. An area on an upper surface of the first molding member, which does not overlap the dummy chip in a vertical direction, includes a modified area. A footprint of the base chip is larger than a footprint of the plurality of first semiconductor chips. The semiconductor chip pad on the lower surface of a lowermost first semiconductor chip from among the plurality of first semiconductor chips contacts the base chip pad in the vertical direction, the first dielectric layer on the upper surface of the base chip contacts the second dielectric layer on the lower surface of the lowermost first semiconductor chip in the vertical direction. A density of the modified area is lower than a density of an area of the first molding member other than the modified area. The area on the upper surface of the first molding member, which does not overlap the dummy chip in the vertical direction, is rougher than a lower surface of the first molding member.

Some example embodiments of the inventive concepts further provide a method of manufacturing a semiconductor package including sequentially stacking a plurality of first semiconductor chips on a base chip in a vertical direction; forming a first molding member on the base chip, the first molding member surrounding side surfaces of the plurality of first semiconductor chips; forming an adhesive layer on an uppermost first semiconductor chip from among the plurality of first semiconductor chips; mounting a dummy chip on the adhesive layer; removing by-products from an upper surface of the first molding member, the by-products generated during the forming of the adhesive layer; and subsequent to the removing of the by-products, forming a second molding member on the upper surface of the first molding member, the second molding member surrounding respective side surfaces of the adhesive layer and the dummy chip.

In some example embodiments of the method of manufacturing the semiconductor package, the removing of the by-products includes performing a laser drilling process on the upper surface of the first molding member.

In some example embodiments of the method of manufacturing the semiconductor package, the performing of the laser drilling process roughens the upper surface of the first molding member.

In some example embodiments of the method of manufacturing the semiconductor package, the performing of the laser drilling process forms a modified area on and in the upper surface of the first molding member, and a density of the modified area may be lower than a density of a lower area of the first molding member.

In some example embodiments of the method of manufacturing the semiconductor package, the forming of the second molding member includes forming the second molding member as having a thermal expansion coefficient different than a thermal expansion coefficient of the first molding member.

In some example embodiments of the method of manufacturing the semiconductor package, the forming of the adhesive layer includes forming at least a portion of the adhesive layer as overlapping the first molding member in the vertical direction, and the mounting of the dummy chip includes disposing at least a portion of the dummy chip as overlapping the first molding member in the vertical direction.

In some example embodiments, the method of manufacturing the semiconductor package, further includes providing the base chip as including a base chip pad and a first dielectric layer on the base chip, with the first dielectric layer surrounding a side surface of the base chip pad; providing a lowermost first semiconductor chip from among the plurality of first semiconductor chips as including a semiconductor chip pad and a second dielectric layer on a lower surface of the lowermost first semiconductor chip, with the second dielectric layer surrounding a side surface of the semiconductor chip pad; and contacting the semiconductor chip pad and the base chip pad in the vertical direction, and contacting the first dielectric layer and the second dielectric layer in the vertical direction.

In some example embodiments of the method of manufacturing the semiconductor package, a footprint of the adhesive layer and a footprint of the dummy chip are larger than a footprint of the plurality of first semiconductor chips.

### BRIEF DESCRIPTION OF THE DRAWINGS

Some example embodiments of the inventive concepts will be more clearly understood from the following detailed description taken in conjunction with the accompanying drawings in which:

FIG. 1 is a cross-sectional view schematically illustrating a semiconductor package according to some example embodiments;

FIG. 2 is a cross-sectional view schematically illustrating a semiconductor package according to some example embodiments;

FIG. 3 is a cross-sectional view schematically illustrating a semiconductor package according to some example embodiments;

FIG. 4 is an enlarged view of portion AA of FIG. 3;

FIG. 5 is a cross-sectional view schematically illustrating a semiconductor package according to some example embodiments;

FIGS. 6, 7, 8, 9, 10, 11 and 12 are cross-sectional views for describing a method of manufacturing semiconductor packages, according to some example embodiments;

FIG. 13 is a cross-sectional view schematically illustrating a semiconductor package according to some example embodiments; and

FIG. 14 is a cross-sectional view schematically illustrating a semiconductor package according to some example embodiments.

### DETAILED DESCRIPTION OF THE SOME EXAMPLE EMBODIMENTS

Hereinafter, some example embodiments are described in detail with reference to the accompanying drawings. Like reference numerals in the drawings denote like elements, and thus their repetitive description will be omitted.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

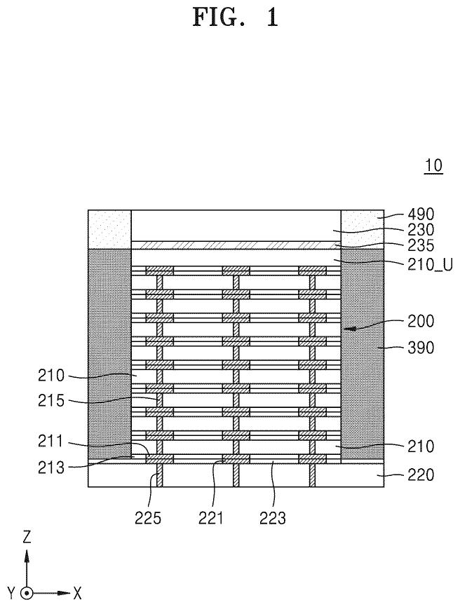

FIG. 1 is a cross-sectional view schematically illustrating a semiconductor package 10 according to some example embodiments.

Referring to FIG. 1, the semiconductor package 10 may include a chip-stacked structure 200, a first molding member 390, and a second molding member 490. The chip-stacked structure 200 may include a base chip 220, a first semiconductor chip 210, an adhesive layer 235, and a dummy chip 230. The base chip 220 may be the lowermost chip in the chip-stacked structure 200. According to some example embodiments, at least one of the upper surface and the lower surface of the base chip 220 may have a flat shape.

In the drawings below, the X-axis direction and the Y-axis direction may be parallel to the upper surface of the base chip 220. The X-axis direction may be perpendicular to the Y-axis direction. The Z-axis direction may be perpendicular to the X-axis direction and the Y-axis direction. In the drawings below, a first horizontal direction, a second horizontal direction, and the vertical direction may be understood as follows. The first horizontal direction may be understood as the X-axis direction, the second horizontal direction may be understood as the Y-axis direction, and the vertical direction may be understood as the Z-axis direction.

According to some example embodiments, the base chip 220 may integrate signals of a plurality of first semiconductor chips 210 stacked on the base chip 220 and transmit the same to the outside, or transmit a signal and power from the outside to the plurality of first semiconductor chips 210. Accordingly, the base chip 220 may be referred to as a buffer chip or a control chip in the specification. According to some example embodiments, the base chip 220 may have a footprint larger than that of the first semiconductor chip 210, as shown in FIG. 1, but is not limited thereto, and the base chip 220 may have a footprint the same or substantially the same as that of the first semiconductor chip 210. As shown in FIG. 1, the horizontal width of the base chip 220 may be greater than the horizontal width of the first semiconductor chip 210 but is not limited thereto, and the horizontal width of the base chip 220 may be the same or substantially the same as the horizontal width of the first semiconductor chip 210. In some example embodiments, the side surface of the base chip 220 may be coplanar with the side surface of the first semiconductor chip 210.

The base chip 220 may include various types of individual devices. The individual devices may include various microelectronics devices, e.g., a metal-oxide-semiconductor field effect transistor (MOSFET), such as a complementary metal-oxide-semiconductor (CMOS) transistor, a system large scale integration (LSI) chip, an image sensor, such as a CMOS imaging sensor (CIS), a micro-electro-mechanical system (MEMS), an active device, a passive device, and the like. In some example embodiments, the base chip 220 may not include a memory cell. For example, a semiconductor device included in the base chip 220 may include a serial-parallel conversion circuit, a test logic circuit, such as a design for test (DFT) circuit, a joint test action group (JTAG) circuit, or a memory built-in self-test (MBIST) circuit, and a signal interface circuit, such as a physical layer (PHY) circuit.

A through electrode 225 passing through the base chip 220 in the vertical direction Z may be located inside the base chip 220. The through electrode 225 may be in contact with a base chip pad 221 on the upper surface of the base chip 220. The through electrode 225 may be electrically connected to the base chip pad 221.

The base chip pad 221 and a dielectric layer 223 may be on the upper surface of the base chip 220. The dielectric layer 223 may surround the base chip pad 221. The dielectric layer 223 may surround the side surface of the base chip pad 221. The upper surface of the base chip pad 221 may be exposed upward from the dielectric layer 223 in the vertical direction Z.

The first semiconductor chip 210 may be stacked on the base chip 220 in the vertical direction Z. The first semiconductor chip 210 may be bonded onto the base chip 220 through direct bonding. The direct bonding may include dielectric-to-dielectric bonding, copper (Cu)-to-Cu bonding, and hybrid bonding that is a combination of dielectric-to-dielectric bonding and metal-to-metal bonding. The direct bonding may be diffusion bonding of arranging two interfaces including the same material to face each other, then bringing the two interfaces into contact with each other, and applying heat to the same such that the two interfaces are integrated through diffusion of metal atoms or dielectric materials coming into contact with each other. The hybrid bonding may include hybrid copper bonding (HCB).

The first semiconductor chip 210 may be bonded to the base chip 220 by the direct bonding. For example, a semiconductor chip pad 211 and a dielectric layer 213 on the lower surface of the lowermost first semiconductor chip 210 may be in contact with the base chip pad 221 and the dielectric layer 223 on the upper surface of the base chip 220 in the vertical direction Z, respectively. Particularly, the semiconductor chip pad 211 on the lower surface of the lowermost first semiconductor chip 210 may be in contact with the base chip pad 221 on the upper surface of the base chip 220 in the vertical direction Z, and the dielectric layer 213 on the lower surface of the lowermost first semiconductor chip 210 may be in contact with the dielectric layer 223 on the upper surface of the base chip 220 in the vertical direction Z. Herein, the semiconductor chip pad 211 and the dielectric layer 213 on the lower surface of the lowermost first semiconductor chip 210 may be bonded to the base chip pad 221 and the dielectric layer 223 on the upper surface of the base chip 220 by direct bonding, respectively. Although FIG. 1 shows that there exists an interface between the semiconductor chip pad 211 and the dielectric layer 213 on the lower surface of the lowermost first semiconductor chip 210 and the base chip pad 221 and the dielectric layer 223 on the upper surface of the base chip 220, the interface may disappear after the direct bonding is performed between the semiconductor chip pad 211 and the dielectric layer 213 on the lower surface of the lowermost first semiconductor chip 210 and the base chip pad 221 and the dielectric layer 223 on the upper surface of the base chip 220.

According to some example embodiments, a plurality of first semiconductor chips 210 may be provided. The plurality of first semiconductor chips 210 may be defined as chips stacked on the base chip 220 in the vertical direction Z and located under the dummy chip 230 among a plurality of chips included in the chip-stacked structure 200. According to some example embodiments, the first semiconductor chip 210 may be referred to as a memory chip or a core chip.

According to some example embodiments, the first semiconductor chip 210 may include the semiconductor chip pad 211, the dielectric layer 213, and a through electrode 215. The semiconductor chip pad 211 may be provided on each of the upper surface and the lower surface of the first semiconductor chip 210. The dielectric layer 213 may surround the semiconductor chip pad 211 on each of the upper surface and the lower surface of the first semiconductor chip 210. In some example embodiments, the dielectric layer 213 may surround the side surface of the semiconductor chip pad 211, and any one of the upper surface and the lower surface of the semiconductor chip pad 211 may be exposed from the dielectric layer 213 in the vertical direction Z.

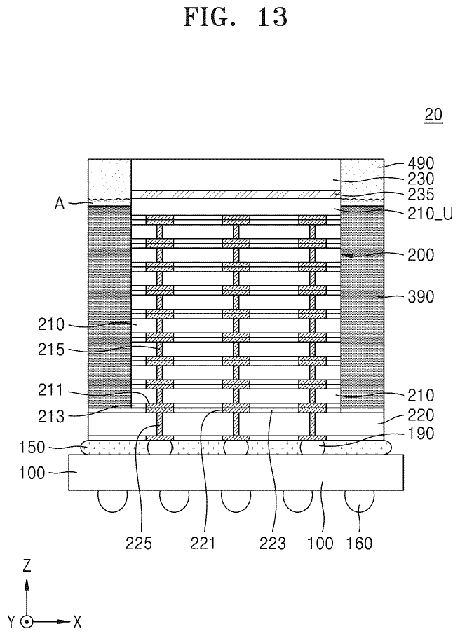

The first semiconductor chip 210 may include a first semiconductor substrate. The first semiconductor substrate may have a lower surface and an upper surface opposite to each other. The lower surface of the first semiconductor substrate may be a surface facing a first substrate 100 (see FIG. 13). The lower surface of the first semiconductor substrate may be referred to as an active surface, and the upper surface opposite to the lower surface of the first semiconductor substrate may be referred to as an inactive surface.

The first semiconductor substrate may include silicon (Si), e.g., monocrystalline Si, polycrystalline Si, or amorphous Si. Alternatively, the first semiconductor substrate may include a semiconductor element, such as germanium (Ge), or a compound semiconductor, such as silicon carbide (SiC), gallium arsenide (GaAs), indium arsenide (InAs), or indium phosphide (InP). The first semiconductor substrate may have a silicon on insulator (SOI) structure. For example, the first semiconductor substrate may include a buried oxide (BOX) layer. The first semiconductor substrate may include a conductive area, e.g., an impurity-doped well or an impurity-doped structure. The first semiconductor substrate may have various device isolation structures, such as a shallow trench isolation (STI) structure.

The first semiconductor chip 210 may include a first semiconductor device layer. According to some example embodiments, the first semiconductor device layer may be formed on the lower surface of the first semiconductor substrate, which is the active surface of the first semiconductor substrate. The first semiconductor device layer may include a core area and a first dummy area. Individual devices may be formed in the core area of the first semiconductor device layer. The individual devices may include various microelectronics devices, e.g., a MOSFET, such as a CMOS transistor, a system LSI chip, an image sensor, such as a CIS, an MEMS, an active device, a passive device, and the like.

The first semiconductor chip 210 may include a first wiring layer. The first wiring layer may be spaced apart from the first semiconductor substrate with the first semiconductor device layer therebetween in the vertical direction Z. The first wiring layer may be electrically connected to the first semiconductor device layer. The first wiring layer may include multi-layer-structured wiring patterns and a via connecting the wiring patterns to each other.

The through electrode 215 may pass through the first semiconductor substrate of the first semiconductor chip 210 in the vertical direction Z. The through electrode 215 may pass through the first semiconductor device layer and the first semiconductor substrate. The through electrode 215 may be electrically connected to the wiring patterns included in the first wiring layer. The through electrode 215 may have a tapered shape of which the horizontal width gradually decreases or increases as the vertical level of the through electrode 215 increases. At least a portion of the through electrode 215 may have a pillar shape. The through electrode 215 may be a through silicon via (TSV). According to some example embodiments, an uppermost first semiconductor chip 210_U among the plurality of first semiconductor chips 210 may not include the through electrode 215.

According to some example embodiments, the surface roughness of the upper surface of the uppermost first semiconductor chip 210_U may be greater than the surface roughness of the upper surface of each of the other first semiconductor chips 210.

In some example embodiments, the thickness of the uppermost first semiconductor chip 210_U among the plurality of first semiconductor chips 210 in the vertical direction Z may be the same or substantially the same as the thickness of each of the other first semiconductor chips 210 in the vertical direction Z.

The plurality of first semiconductor chips 210 may be stacked in a line in the vertical direction Z. For example, the respective side surfaces of the plurality of first semiconductor chips 210 may be coplanar with each other. However, the plurality of first semiconductor chips 210 are not limited thereto and may be stacked offset in one direction.

In some example embodiments, the plurality of first semiconductor chips 210 may be stacked in the vertical direction Z through direct bonding. For example, the semiconductor chip pad 211 and the dielectric layer 213 on the upper surface of a certain first semiconductor chip 210 may be in contact with the semiconductor chip pad 211 and the dielectric layer 213 on the lower surface of a first semiconductor chip 210 on the certain first semiconductor chip 210 in the vertical direction Z, respectively. Particularly, the semiconductor chip pad 211 on the upper surface of the certain first semiconductor chip 210 may be in contact with the semiconductor chip pad 211 on the lower surface of the first semiconductor chip 210 on the certain first semiconductor chip 210 in the vertical direction Z, and the dielectric layer 213 on the upper surface of the certain first semiconductor chip 210 may be in contact with the dielectric layer 213 on the lower surface of the first semiconductor chip 210 on the certain first semiconductor chip 210 in the vertical direction Z. Herein, the semiconductor chip pad 211 and the dielectric layer 213 on the upper surface of the certain first semiconductor chip 210 may be bonded to the semiconductor chip pad 211 and the dielectric layer 213 on the lower surface of the first semiconductor chip 210 on the certain first semiconductor chip 210 by direct bonding, respectively. Although FIG. 1 shows that there exists an interface between the semiconductor chip pad 211 and the dielectric layer 213 on the upper surface of the certain first semiconductor chip 210 and the semiconductor chip pad 211 and the dielectric layer 213 on the lower surface of the first semiconductor chip 210 on the certain first semiconductor chip 210, the interface may disappear after the direct bonding is performed between the semiconductor chip pad 211 and the dielectric layer 213 on the upper surface of the certain first semiconductor chip 210 and the semiconductor chip pad 211 and the dielectric layer 213 on the lower surface of the first semiconductor chip 210 on the certain first semiconductor chip 210.

Because the plurality of first semiconductor chips 210 are stacked through direct bonding, an adhesive layer and a bump may not be provided between the plurality of first semiconductor chips 210.

According to some example embodiments, the length of the first semiconductor chip 210 in a first horizontal direction X may be less than the length of the base chip 220 in the first horizontal direction X. The footprint of the first semiconductor chip 210 may be smaller than the footprint of the base chip 220. However, the length and the footprint of the first semiconductor chip 210 are not limited thereto, and the length of the first semiconductor chip 210 in the first horizontal direction X may be the same or substantially the same as the length of the base chip 220 in the first horizontal direction X. The footprint of the first semiconductor chip 210 may be the same or substantially the same as the footprint of the base chip 220.

According to some example embodiments, the first semiconductor chip 210 may include a memory chip. The memory chip may be, for example, a volatile memory chip, such as dynamic random access memory (DRAM) or static random access memory (SRAM), or a non-volatile memory chip, such as phase-change random access memory (PRAM), magnetoresistive random access memory (MRAM), ferroelectric random access memory (FeRAM), or resistive random access memory (RRAM). According to some example embodiments, the memory chip may be a high bandwidth memory (HBM) package or a wire-bonding memory package, in which a plurality of memory chips are stacked in the vertical direction Z. However, the first semiconductor chip 210 is not limited thereto and may include a logic chip, such as a microprocessor, such as a central processing unit (CPU), a graphics processing unit (GPU), or an application processor (AP), an analog device, or a digital signal processor.

The dummy chip 230 may be stacked on the uppermost first semiconductor chip 210_U in the vertical direction Z. The dummy chip 230 may be stacked on the uppermost first semiconductor chip 210_U through the adhesive layer 235. According to some example embodiments, the dummy chip 230 may not be electrically connected to the uppermost first semiconductor chip 210_U. In some example embodiments, the thickness of the dummy chip 230 in the vertical direction Z may be greater than the thickness of the first semiconductor chip 210 in the vertical direction Z.

The adhesive layer 235 may be between the dummy chip 230 and the uppermost first semiconductor chip 210_U. In some example embodiments, the adhesive layer 235 may be configured to attach the dummy chip 230 onto the uppermost first semiconductor chip 210_U. The adhesive layer 235 may be a film having an adhesion property. For example, the adhesive layer 235 may be a double-sided adhesive film. According to some example embodiments, the adhesive layer 235 may include a tape-type material layer, a liquified coating cure material layer, or a combination thereof. Alternatively, the adhesive layer 235 may include a thermal setting structure, thermal plastic, an ultraviolet (UV) cure material, or a combination thereof. The adhesive layer 235 may be referred to as a die attach film (DAF) or a non-conductive film (NCF).

In some example embodiments, the footprint of the adhesive layer 235 may be the same or substantially the same as the footprint of the uppermost first semiconductor chip 210_U. The footprint of the dummy chip 230 may be the same or substantially the same as the footprint of the adhesive layer 235.

The first molding member 390 may be formed on the upper surface of the base chip 220 to surround the plurality of first semiconductor chips 210. For example, the first molding member 390 may surround the side surfaces of the plurality of first semiconductor chips 210 on the upper surface of the base chip 220. The first molding member 390 may be formed of a molding material, such as an epoxy mold compound (EMC), or a photosensitive material, such as a photoimageable encapsulant (PIE). In some example embodiments, a portion of the first molding member 390 may be formed of an insulating material, such as a silicon oxide film, a silicon nitride film, or a silicon oxynitride film. However, the first molding member 390 is not limited thereto and may be formed of a thermosetting resin, such as an epoxy resin, a thermoplastic resin, such as polyimide, or a resin including a reinforcing material, such as an inorganic filler, thereto, particularly, an Ajinomoto build-up film (ABF), flame retardant class 4 (FR-4), bismaleimide triazine (BT), or the like.

According to some example embodiments, the upper surface of the first molding member 390 may be coplanar with the upper surface of the uppermost first semiconductor chip 210_U. For example, the vertical level of the upper surface of the first molding member 390 may be the same or substantially the same as the vertical level of the upper surface of the uppermost first semiconductor chip 210_U.

According to some example embodiments, a laser drilling process may be performed on an area on the upper surface of the first molding member 390, which does not overlap the dummy chip 230 in the vertical direction Z. The upper surface of the first molding member 390, on which laser drilling has been performed, may have roughness because a material is removed by a laser process and a thermal influence is applied thereto. The roughness of the upper surface of the first molding member 390 may include micro grooves, concaves/convexes, or micro protrusion portions generated in a drilling process. The area on the upper surface of the first molding member 390, which does not overlap the dummy chip 230 in the vertical direction Z, may have a bumpy shape. According to some example embodiments, the roughness of the area on the upper surface of the first molding member 390, which does not overlap the dummy chip 230 in the vertical direction Z, may be greater than the roughness of the lower surface of the first molding member 390. The roughness of the area of the upper surface of the first molding member 390, which does not overlap the dummy chip 230 in the vertical direction Z, may be greater than the roughness of the upper surface of the second molding member 490.

The second molding member 490 may surround the adhesive layer 235 and the dummy chip 230 on the upper surface of the first molding member 390. According to some example embodiments, the upper surface of the second molding member 490 may be coplanar with the upper surface of the dummy chip 230.

According to some example embodiments, the second molding member 490 may be formed of a molding material, such as an EMC, or a photosensitive material, such as a PIE. In some example embodiments, a portion of the second molding member 490 may be formed of an insulating material, such as a silicon oxide film, a silicon nitride film, or a silicon oxynitride film. However, the second molding member 490 is not limited thereto and may be formed of a thermosetting resin, such as an epoxy resin, a thermoplastic resin, such as polyimide, or a resin including a reinforcing material, such as an inorganic filler, and an ABF, FR-4, BT, or the like. In some example embodiments, the second molding member 490 may include a material that is different from that of the first molding member 390. For example, the second molding member 490 may include a material having a thermal expansion coefficient that is different from that of the first molding member 390. When the thermal expansion coefficient of the first molding member 390 is different from the thermal expansion coefficient of the second molding member 490, warpage of the semiconductor package 10 may be limited and/or prevented. When the first molding member 390 and the second molding member 490 have different thermal expansion coefficients, in a process of forming the first molding member 390 and the second molding member 490, expansion or contraction of the first molding member 390 and the second molding member 490 due to heat may be offset. For example, when the first molding member 390 has a relatively higher thermal expansion coefficient than the second molding member 490, stress applied to the semiconductor package 10 may be balanced by a force in the opposite direction.

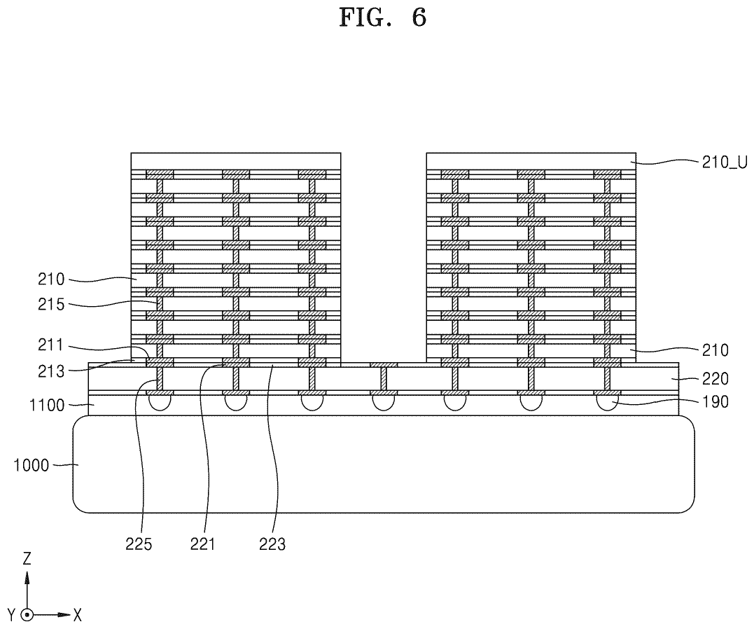

In the semiconductor package 10 according to some example embodiments of the inventive concepts, as to be described below with reference to FIGS. 6 to 12, the plurality of first semiconductor chips 210 may be stacked on the base chip 220, then the first molding member 390 may be formed through primary molding to surround the side surfaces of the plurality of first semiconductor chips 210, and the dummy chip 230 may be mounted on the uppermost first semiconductor chip 210_U through the adhesive layer 235. Thereafter, by-products, which are generated in a process of forming the adhesive layer 235 and remain on the surface exposed from the adhesive layer 235 on the upper surface of the first molding member 390, may be removed through a laser drilling process. After removing the by-products, the second molding member 490 surrounding the respective side surfaces of the adhesive layer 235 and the dummy chip 230 may be formed through secondary molding.

Because a molding process is primarily performed before forming the adhesive layer 235 and the dummy chip 230, by-products due to the adhesive layer 235 may not remain between the base chip 220 and the first molding member 390. Accordingly, adhesion between the base chip 220 and the first molding member 390 may be reinforced, and generation of cracks, voids, and the like between the base chip 220 and the first molding member 390 may be limited and/or prevented.

Before performing a secondary molding process of forming the second molding member 490, the by-products due to the adhesive layer 235 remaining on the upper surface of the first molding member 390 may be removed through a laser drilling process, and thus, the adhesive force between the first molding member 390 and the second molding member 490 may be reinforced. Furthermore, the generation of cracks, voids, and the like between the first molding member 390 and the second molding member 490 may be reduced.

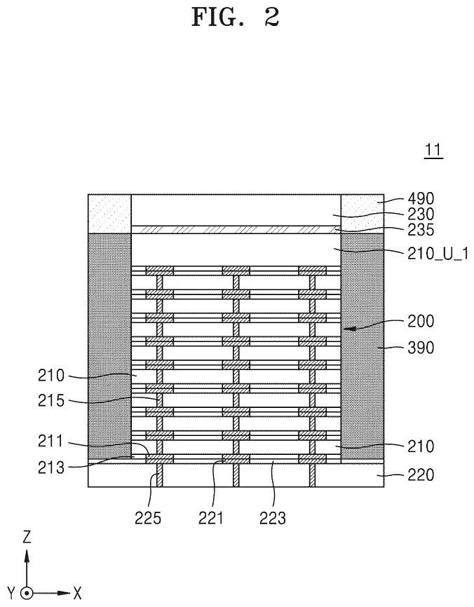

FIG. 2 is a cross-sectional view schematically illustrating a semiconductor package 11 according to some example embodiments. Hereinafter, the description made with respect to the semiconductor package 10 with reference to FIG. 1 is not repeated, and differences between the semiconductor package 10 of FIG. 1 and the semiconductor package 11 of FIG. 2 are mainly described.

Referring to FIG. 2, the semiconductor package 11 may include the chip-stacked structure 200, the first molding member 390, and the second molding member 490. The chip-stacked structure 200 may include the base chip 220, the first semiconductor chip 210, the adhesive layer 235, and the dummy chip 230. The base chip 220 may be the lowermost chip in the chip-stacked structure 200. The through electrode 225 passing through the base chip 220 in the vertical direction Z may be located inside the base chip 220. The first semiconductor chip 210 may be stacked on the base chip 220 in the vertical direction Z. The base chip pad 221 and the dielectric layer 223 may be on the upper surface of the base chip 220. The dielectric layer 223 may surround the base chip pad 221. The dielectric layer 223 may surround the side surface of the base chip pad 221. The upper surface of the base chip pad 221 may be exposed upward from the dielectric layer 223 in the vertical direction Z. According to some example embodiments, a plurality of first semiconductor chips 210 may be provided. The plurality of first semiconductor chips 210 may be stacked in the vertical direction Z by direct bonding.

According to some example embodiments, the first semiconductor chip 210 may include the semiconductor chip pad 211, the dielectric layer 213, and the through electrode 215. The semiconductor chip pad 211 may be provided on each of the upper surface and the lower surface of the first semiconductor chip 210. The dielectric layer 213 may surround the semiconductor chip pad 211 on each of the upper surface and the lower surface of the first semiconductor chip 210. In some example embodiments, the dielectric layer 213 may surround the side surface of the semiconductor chip pad 211, and any one of the upper surface and the lower surface of the semiconductor chip pad 211 may be exposed from the dielectric layer 213 in the vertical direction Z. According to some example embodiments, an uppermost first semiconductor chip 210_U_1 among the plurality of first semiconductor chips 210 may not include the through electrode 215.

According to some example embodiments, the surface roughness of the upper surface of the uppermost first semiconductor chip 210_U_1 may be greater than the surface roughness of the upper surface of each of the other first semiconductor chips 210.

According to some example embodiments, the thickness of the uppermost first semiconductor chip 210_U_1 in the vertical direction Z may be greater than the thickness of each of the other first semiconductor chips 210 in the vertical direction Z.

The upper surface of the uppermost first semiconductor chip 210_U_1 may be exposed upward from the first molding member 390 in the vertical direction Z and be in contact with the adhesive layer 235.

The first molding member 390 may be formed by a primary molding process of performing over-molding such that the first molding member 390 covers the upper surface of the uppermost first semiconductor chip 210_U_1, and thus, a process of exposing the upper surface of the uppermost first semiconductor chip 210_U_1 through a chemical mechanical polishing (CMP) process or the like may be required. By performing the CMP process, the upper surface of the uppermost first semiconductor chip 210_U_1 may be removed up to a certain depth.

The first molding member 390 may be formed on the upper surface of the base chip 220 to surround the plurality of first semiconductor chips 210. For example, the first molding member 390 may surround the side surfaces of the plurality of first semiconductor chips 210 on the upper surface of the base chip 220.

When the thickness of the uppermost first semiconductor chip 210_U_1 in the vertical direction Z is greater than the thickness of each of the other first semiconductor chips 210 in the vertical direction Z, even if a CMP process of removing the uppermost first semiconductor chip 210_U_1 and the first molding member 390 up to the certain depth is performed, it may be easy to adjust the thickness of the uppermost first semiconductor chip 210_U_1.

The dummy chip 230 may be stacked on the uppermost first semiconductor chip 210_U_1 in the vertical direction Z. The dummy chip 230 may be stacked on the uppermost first semiconductor chip 210_U_1 through the adhesive layer 235.

According to some example embodiments, a laser drilling process may be performed on an area on the upper surface of the first molding member 390, which does not overlap the dummy chip 230 in the vertical direction Z.

The second molding member 490 may surround the adhesive layer 235 and the dummy chip 230 on the upper surface of the first molding member 390. According to some example embodiments, the upper surface of the second molding member 490 may be coplanar with the upper surface of the dummy chip 230.

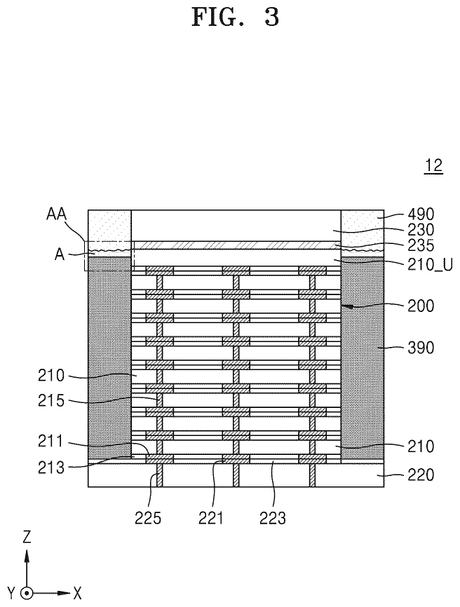

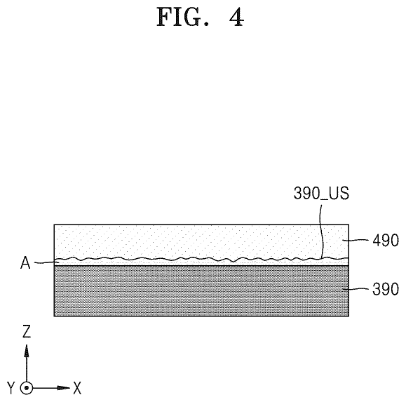

FIG. 3 is a cross-sectional view schematically illustrating a semiconductor package 12 according to some example embodiments. FIG. 4 is an enlarged view of portion AA of FIG. 3. Hereinafter, the description made with respect to the semiconductor package 10 with reference to FIG. 1 is not repeated, and differences between the semiconductor package 10 of FIG. 1 and the semiconductor package 12 of FIG. 3 are mainly described.

Referring to FIGS. 3 and 4, the semiconductor package 12 may include the chip-stacked structure 200, the first molding member 390, and the second molding member 490. The chip-stacked structure 200 may include the base chip 220, the first semiconductor chip 210, the adhesive layer 235, and the dummy chip 230. The base chip 220 may be the lowermost chip in the chip-stacked structure 200. The through electrode 225 passing through the base chip 220 in the vertical direction Z may be located inside the base chip 220. The first semiconductor chip 210 may be stacked on the base chip 220 in the vertical direction Z. The base chip pad 221 and the dielectric layer 223 may be on the upper surface of the base chip 220. The dielectric layer 223 may surround the base chip pad 221. The dielectric layer 223 may surround the side surface of the base chip pad 221. The upper surface of the base chip pad 221 may be exposed upward from the dielectric layer 223 in the vertical direction Z. According to some example embodiments, a plurality of first semiconductor chips 210 may be provided. The plurality of first semiconductor chips 210 may be stacked in the vertical direction Z by direct bonding.

According to some example embodiments, the first semiconductor chip 210 may include the semiconductor chip pad 211, the dielectric layer 213, and the through electrode 215. The semiconductor chip pad 211 may be provided on each of the upper surface and the lower surface of the first semiconductor chip 210. The dielectric layer 213 may surround the semiconductor chip pad 211 on each of the upper surface and the lower surface of the first semiconductor chip 210. In some example embodiments, the dielectric layer 213 may surround the side surface of the semiconductor chip pad 211, and any one of the upper surface and the lower surface of the semiconductor chip pad 211 may be exposed from the dielectric layer 213 in the vertical direction Z. According to some example embodiments, the uppermost first semiconductor chip 210_U among the plurality of first semiconductor chips 210 may not include the through electrode 215.

According to some example embodiments, the surface roughness of the upper surface of the uppermost first semiconductor chip 210_U may be greater than the surface roughness of the upper surface of each of the other first semiconductor chips 210.

The first molding member 390 may be formed on the upper surface of the base chip 220 to surround the plurality of first semiconductor chips 210. For example, the first molding member 390 may surround the side surfaces of the plurality of first semiconductor chips 210 on the upper surface of the base chip 220.

The dummy chip 230 may be stacked on the uppermost first semiconductor chip 210_U in the vertical direction Z. The dummy chip 230 may be stacked on the uppermost first semiconductor chip 210_U through the adhesive layer 235.

According to some example embodiments, a laser drilling process may be performed on an area on the upper surface of the first molding member 390, which does not overlap the dummy chip 230 in the vertical direction Z.

An upper surface 390_US of the first molding member 390, which does not overlap the dummy chip 230 in the vertical direction Z, may have a bumpy shape. The lower surface of the second molding member 490 on the upper surface 390_US of the first molding member 390 may have a bumpy shape. In some example embodiments, no empty spaces may be provided between the upper surface 390_US of the first molding member 390 and the lower surface of the second molding member 490.

According to some example embodiments, the area on the upper surface of the first molding member 390, which does not overlap the dummy chip 230 in the vertical direction Z, may include a modified area A. The modified area A may be located on the surface and in the inside of the area on the upper surface of the first molding member 390, which does not overlap the dummy chip 230 in the vertical direction Z. According to some example embodiments, the modified area A may be continuously formed up to a certain depth from the surface of the area on the upper surface of the first molding member 390, which does not overlap the dummy chip 230 in the vertical direction Z. According to some example embodiments, the density of the modified area A may be lower than the density of a lower area of the first molding member 390.

The modified area A may be formed by a laser drilling process performed on the area on the upper surface of the first molding member 390, which does not overlap the dummy chip 230 in the vertical direction Z. The modified area A may be generated in a process of locally heating a material by a high energy laser so as to be deformed.

The laser drilling process may be performed to effectively remove by-products which may remain on the surface of the first molding member 390. In some example embodiments, a laser may be irradiated on the upper surface of the first molding member 390 with high energy to vaporize volatile materials, thereby removing the by-products. Herein, it may be understood that the upper surface of the first molding member 390 is the upper surface of the area on the upper surface of the first molding member 390, which does not overlap the dummy chip 230 in the vertical direction Z. According to some example embodiments, the modified area A may not overlap the adhesive layer 235 in the vertical direction Z.

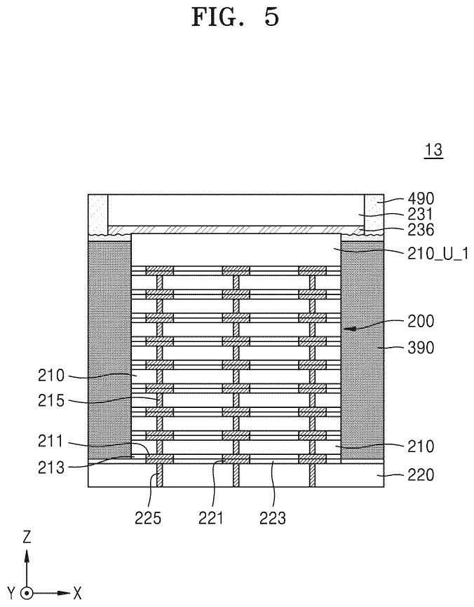

FIG. 5 is a cross-sectional view schematically illustrating a semiconductor package 13 according to some example embodiments. Hereinafter, the description made with reference to FIGS. 1 to 4 is not repeated, and differences from the description are mainly described.

Referring to FIG. 5, the semiconductor package 13 may include the chip-stacked structure 200, the first molding member 390, and the second molding member 490. The chip-stacked structure 200 may include the base chip 220, the first semiconductor chip 210, an adhesive layer 236, and a dummy chip 231. The base chip 220 may be the lowermost chip in the chip-stacked structure 200. The through electrode 225 passing through the base chip 220 in the vertical direction Z may be located inside the base chip 220. The first semiconductor chip 210 may be stacked on the base chip 220 in the vertical direction Z. The base chip pad 221 and the dielectric layer 223 may be on the upper surface of the base chip 220. The dielectric layer 223 may surround the base chip pad 221. The dielectric layer 223 may surround the side surface of the base chip pad 221. The upper surface of the base chip pad 221 may be exposed upward from the dielectric layer 223 in the vertical direction Z. According to some example embodiments, a plurality of first semiconductor chips 210 may be provided. The plurality of first semiconductor chips 210 may be stacked in the vertical direction Z by direct bonding.

According to some example embodiments, the first semiconductor chip 210 may include the semiconductor chip pad 211, the dielectric layer 213, and the through electrode 215. The semiconductor chip pad 211 may be provided on each of the upper surface and the lower surface of the first semiconductor chip 210. The dielectric layer 213 may surround the semiconductor chip pad 211 on each of the upper surface and the lower surface of the first semiconductor chip 210. In some example embodiments, the dielectric layer 213 may surround the side surface of the semiconductor chip pad 211, and any one of the upper surface and the lower surface of the semiconductor chip pad 211 may be exposed from the dielectric layer 213 in the vertical direction Z. According to some example embodiments, the uppermost first semiconductor chip 210_U_1 among the plurality of first semiconductor chips 210 may not include the through electrode 215.

According to some example embodiments, the surface roughness of the upper surface of the uppermost first semiconductor chip 210_U_1 may be greater than the surface roughness of the upper surface of each of the other first semiconductor chips 210.

The first molding member 390 may be formed on the upper surface of the base chip 220 to surround the plurality of first semiconductor chips 210. For example, the first molding member 390 may surround the side surfaces of the plurality of first semiconductor chips 210 on the upper surface of the base chip 220.

The dummy chip 231 may be stacked on the uppermost first semiconductor chip 210_U_1 in the vertical direction Z. The dummy chip 231 may be stacked on the uppermost first semiconductor chip 210_U_1 through the adhesive layer 236.

According to some example embodiments, the footprint of the dummy chip 231 may be larger than the footprint of the uppermost first semiconductor chip 210_U_1. The footprint of the adhesive layer 236 may be larger than the footprint of the uppermost first semiconductor chip 210_U_1.

According to some example embodiments, a portion of each of the dummy chip 231 and the adhesive layer 236 may overlap the first molding member 390 in the vertical direction Z. Because each of the dummy chip 231 and the adhesive layer 236 has a footprint larger than that of the first semiconductor chip 210, heat generated by the first semiconductor chip 210 and the base chip 220 may be easily discharged to the outside of the semiconductor package 13.

According to some example embodiments, a laser drilling process may be performed on an area on the upper surface of the first molding member 390, which does not overlap the dummy chip 231 in the vertical direction Z.

The upper surface 390_US (see FIG. 4) of the first molding member 390, which does not overlap the uppermost first semiconductor chip 210_U_1 in the vertical direction Z, may have a bumpy shape. The lower surface of the second molding member 490 on the upper surface 390_US (see FIG. 4) of the first molding member 390 may have a bumpy shape. In some example embodiments, no empty spaces may be provided between the upper surface 390_US (see FIG. 4) of the first molding member 390 and the lower surface of the second molding member 490.

According to some example embodiments, the area on the upper surface of the first molding member 390, which does not overlap the uppermost first semiconductor chip 210_U_1 in the vertical direction Z, may include the modified area A. The modified area A may be located on the surface and in the inside of the area on the upper surface of the first molding member 390, which does not overlap the dummy chip 231 in the vertical direction Z. According to some example embodiments, the modified area A may be continuously formed up to a certain depth from the surface of the area on the upper surface of the first molding member 390, which does not overlap the dummy chip 231 in the vertical direction Z. According to some example embodiments, the density of the modified area A may be lower than the density of a lower area of the first molding member 390.

FIGS. 6 to 12 are cross-sectional views for describing a method of manufacturing semiconductor packages, according to some example embodiments. Hereinafter, the description made with reference to FIGS. 1 to 5 is not repeated, and differences from the description are mainly described.

Referring to FIG. 6, the base chip 220 and the plurality of first semiconductor chips 210 stacked on the base chip 220 are bonded onto a carrier substrate 1000. The base chip 220 and the plurality of first semiconductor chips 210 may be fixed onto the carrier substrate 1000 through an adhesive layer 1100. The lower surface of the base chip 220 may include a dielectric layer and chip pads thereon.

A first bump 190 may be on the lower surface of the base chip 220. The first bump 190 may include a pillar structure, a ball structure, or a solder layer. The adhesive layer 1100 may surround the first bump 190 on the lower surface of the base chip 220.

According to some example embodiments, the base chip pad 221 and the dielectric layer 223 surrounding the side surface of the base chip pad 221 may be on the upper surface of the base chip 220. The dielectric layer 223 may fully cover the upper surface of the base chip 220.

According to some example embodiments, a plurality of first semiconductor chips 210 may be stacked as a plurality of structures on the base chip 220. For example, as shown in FIG. 6, two structures each having a plurality of first semiconductor chips 210 stacked in the vertical direction Z may be on the base chip 220. The plurality of structures may be spaced apart from each other in a horizontal direction. Although FIG. 6 shows two structures, this is for convenience, and one or more structures may be on the base chip 220.

Each of the plurality of first semiconductor chips 210 may include the semiconductor chip pad 211, the dielectric layer 213, and the through electrode 215. Herein, the uppermost first semiconductor chip 210_U may not include the through electrode 215.

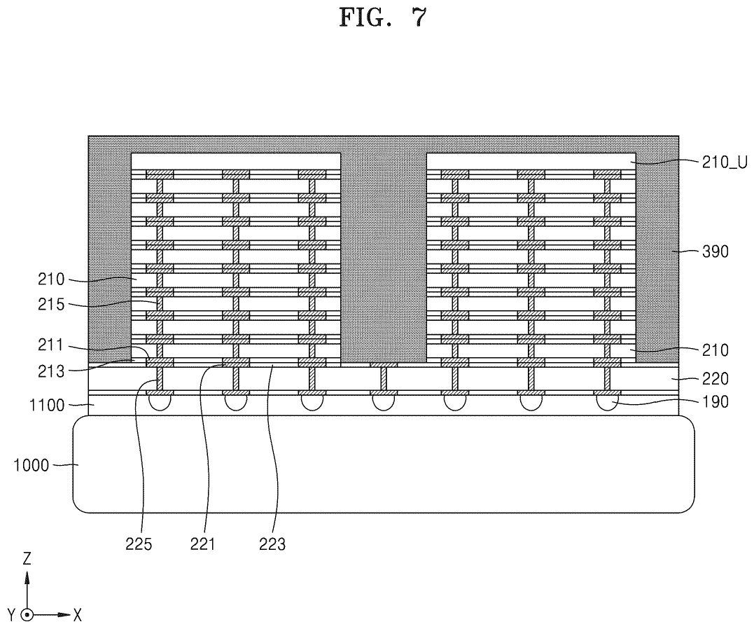

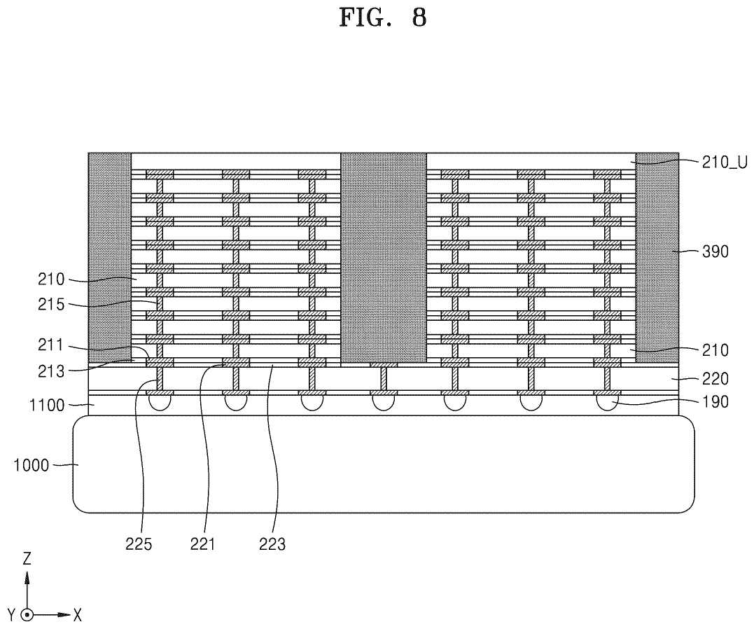

Referring to FIGS. 7 and 8, the first molding member 390 covering the plurality of first semiconductor chips 210 is formed on the base chip 220. The first molding member 390 may cover the plurality of structures on the base chip 220. The first molding member 390 may cover the upper surface of the uppermost first semiconductor chip 210_U.

Thereafter, portions of the first molding member 390 and the uppermost first semiconductor chip 210_U are removed up to a certain depth through a CMP process such that the upper surface of the uppermost first semiconductor chip 210_U is exposed upward in the vertical direction Z. The upper surface of the uppermost first semiconductor chip 210_U may be coplanar with the upper surface of the first molding member 390.

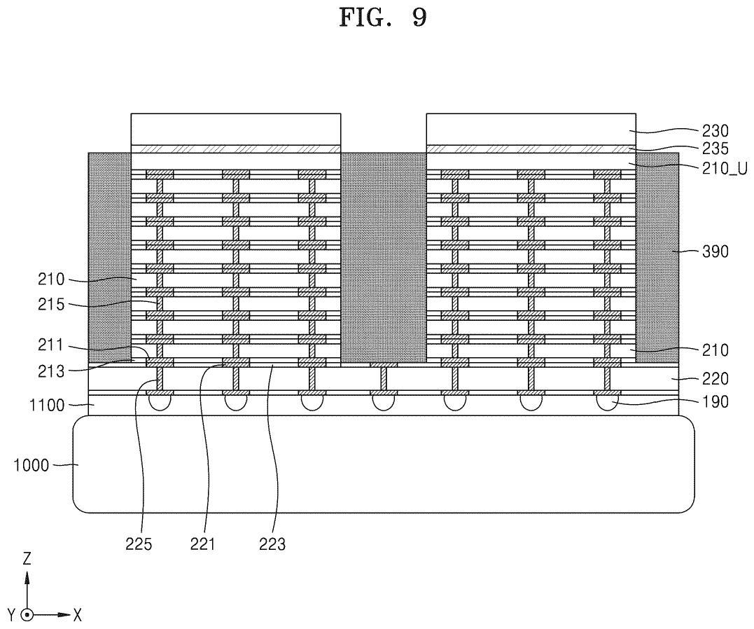

Referring to FIG. 9, the dummy chip 230 is mounted on the upper surface of the uppermost first semiconductor chip 210_U. The dummy chip 230 may be attached onto the upper surface of the uppermost first semiconductor chip 210_U through the adhesive layer 235.

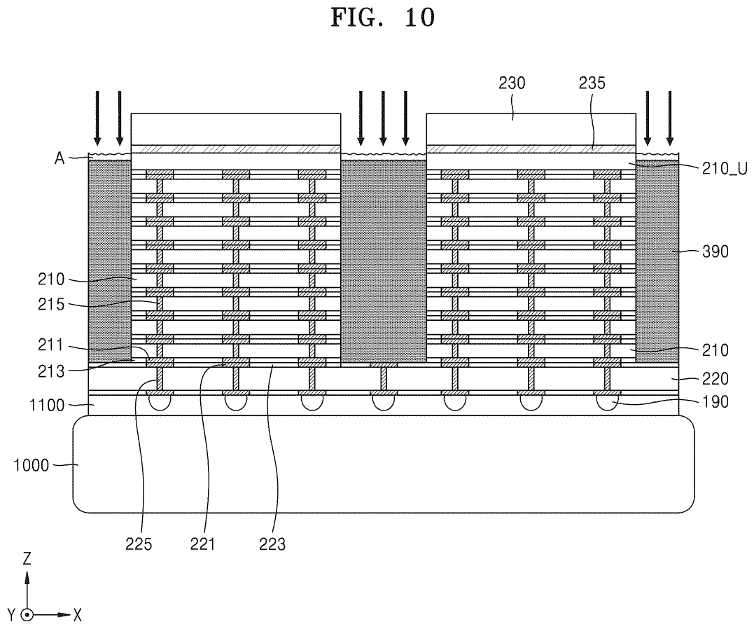

Referring to FIG. 10, a laser drilling process is performed on the upper surface of the first molding member 390. The laser drilling process may be a process of removing by-products, e.g., volatile by-products and the like of the adhesive layer 235, generated while attaching the dummy chip 230 to the uppermost first semiconductor chip 210_U through the adhesive layer 235.

The upper surface of the first molding member 390 on which the laser drilling process is performed may be an area on the upper surface of the first molding member 390, which does not overlap the dummy chip 230 in the vertical direction Z.

The roughness of the area on the upper surface of the first molding member 390, which does not overlap the dummy chip 230 in the vertical direction Z, may be greater than the roughness of each of the upper surface and the side surface of the first molding member 390. The area on the upper surface of the first molding member 390, which does not overlap the dummy chip 230 in the vertical direction Z, may have a surface becoming rough by a laser drilling process. As the roughness of the area on the upper surface of the first molding member 390, which does not overlap the dummy chip 230 in the vertical direction Z, increases, the surface area of the upper surface of the first molding member 390 may increase more than before the laser drilling process is performed. Accordingly, as to be described below, an adhesive force with the second molding member 490 may be reinforced.

According to some example embodiments, the modified area A may be formed on the first molding member 390 by the laser drilling process. The modified area A may be formed up to a certain depth from the area on the upper surface of the first molding member 390, which does not overlap the dummy chip 230 in the vertical direction Z. The density of the modified area A may be lower than the density of an area other than the modified area A.

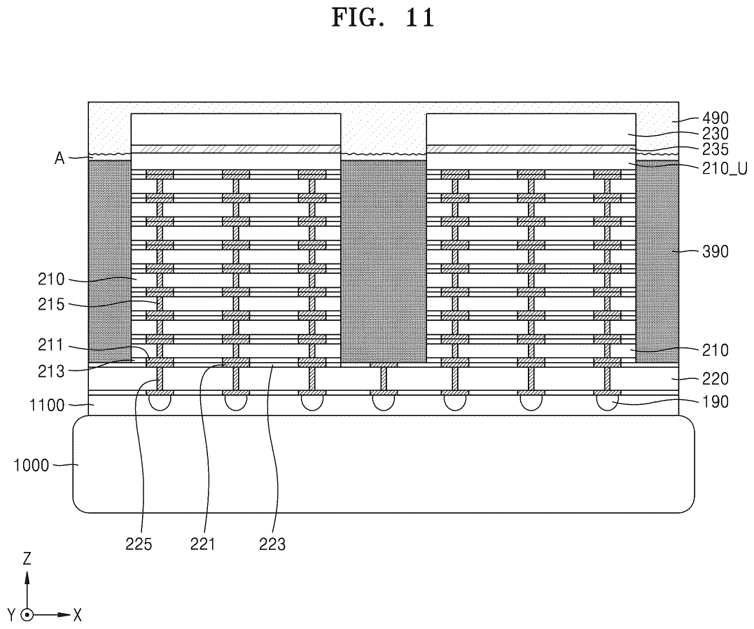

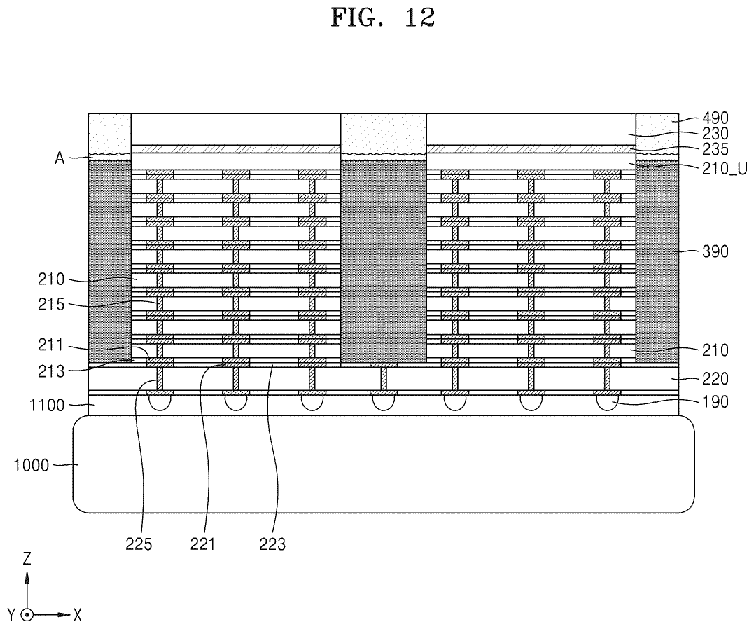

Referring to FIGS. 11 and 12, the second molding member 490 covering the adhesive layer 235 and the dummy chip 230 is formed on the first molding member 390. The second molding member 490 may fully cover the upper surface of the dummy chip 230. Thereafter, the second molding member 490 and the dummy chip 230 are removed up to a certain depth through a CMP process such that the upper surface of the dummy chip 230 is exposed from the second molding member 490.

FIG. 13 is a cross-sectional view schematically illustrating a semiconductor package 20 according to some example embodiments. Hereinafter, the description made with reference to FIGS. 1 to 12 is not repeated, and differences from the description are mainly described.

Referring to FIG. 13, the semiconductor package 20 may include a first substrate 100, the chip-stacked structure 200, the first molding member 390, and the second molding member 490. The first substrate 100 is a substrate on which the chip-stacked structure 200 is mounted, and may be located under the chip-stacked structure 200. Particularly, the first substrate 100 may be between the chip-stacked structure 200 and an external connection terminal 160. The first substrate 100 may be electrically connected to each of the chip-stacked structure 200 and the external connection terminal 160. According to some example embodiments, the first substrate 100 may have a shape in which at least one of the upper and lower surfaces of the first substrate 100 is flat. According to some example embodiments, a plurality of semiconductor packages may be mounted on the first substrate 100, and the plurality of semiconductor packages may be various types of semiconductor packages.

The first substrate 100 may include an insulating layer and a wiring formed in the insulating layer. According to some example embodiments, the first substrate 100 may include a redistribution structure formed through a redistribution process. In some example embodiments, the wiring of the first substrate 100 may be understood as a redistribution pattern, and the insulating layer of the first substrate 100 may be understood as a redistribution insulating layer. Herein, the wiring of the first substrate 100 may include a metal, such as Cu, aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy of the metal but is not limited thereto, and in some some example embodiments, the wiring may be formed by stacking a metal or an alloy of the metal on a seed layer including Cu, Ti, titanium nitride, or titanium tungsten. The insulating layer of the first substrate 100 may be formed of photo imageable dielectric (PID) or photosensitive polyimide (PSPI).

However, the first substrate 100 is not limited thereto, and in some example embodiments, the first substrate 100 may be formed based on a ceramic substrate, a printed circuit board (PCB), an organic substrate, or the like. In some example embodiments, the wiring of the first substrate 100 may include Cu, Ni, stainless steel, or beryllium copper, and the insulating layer of the first substrate 100 may include at least one material selected from among FR-4, tetrafunctional epoxy, polyphenylene ether, epoxy/polyphenylene oxide, BT, Thermount, cyanate ester, polyimide, and liquid crystal polymer.

The external connection terminal 160 may be disposed on the lower surface of the first substrate 100 and electrically connected to the first substrate 100 via a pad formed on the lower surface of the first substrate 100. Particularly, the external connection terminal 160 may be electrically connected to wirings, formed in the first substrate 100, via a substrate pad attached to the lower surface of the first substrate 100. Because the external connection terminal 160 is beneath the first substrate 100, the upper surface of the external connection terminal 160 may be in physical contact with the substrate pad attached to the lower surface of the first substrate 100. The external connection terminal 160 may be electrically connected to an external device, for example, a motherboard, a PCB, a package substrate, or the like. Because the external connection terminal 160 is provided between the external device and the first substrate 100, the lower surface of the external connection terminal 160 may be physically connected to the external device.

The external connection terminal 160 may be formed as a solder ball. However, according to some example embodiments, the external connection terminal 160 may have a structure including a pillar and solder. The external connection terminal 160 may include at least one of Cu, silver (Ag), gold (Au), and Sn.

According to some example embodiments, the chip-stacked structure 200 may be mounted on the upper surface of the first substrate 100 through the first bump 190. The first bump 190 may be provided between the chip-stacked structure 200 and the first substrate 100. The first bump 190 may include a pillar structure, a ball structure, or a solder layer.

According to some example embodiments, an under-fill material layer 150 surrounding the first bump 190 may be provided between the chip-stacked structure 200 and the first substrate 100. The under-fill material layer 150 may include an epoxy resin formed by, for example, a capillary under-fill process.

The chip-stacked structure 200 may include the base chip 220, the first semiconductor chip 210, the adhesive layer 235, and the dummy chip 230. The base chip 220 may be the lowermost chip in the chip-stacked structure 200. The through electrode 225 passing through the base chip 220 in the vertical direction Z may be located inside the base chip 220. The first semiconductor chip 210 may be stacked on the base chip 220 in the vertical direction Z. The base chip pad 221 and the dielectric layer 223 may be on the upper surface of the base chip 220. The dielectric layer 223 may surround the base chip pad 221. The dielectric layer 223 may surround the side surface of the base chip pad 221. The upper surface of the base chip pad 221 may be exposed upward from the dielectric layer 223 in the vertical direction Z. According to some example embodiments, a plurality of first semiconductor chips 210 may be provided. The plurality of first semiconductor chips 210 may be stacked in the vertical direction Z by direct bonding.

According to some example embodiments, the first semiconductor chip 210 may include the semiconductor chip pad 211, the dielectric layer 213, and the through electrode 215. The semiconductor chip pad 211 may be provided on each of the upper surface and the lower surface of the first semiconductor chip 210. The dielectric layer 213 may surround the semiconductor chip pad 211 on each of the upper surface and the lower surface of the first semiconductor chip 210. In some example embodiments, the dielectric layer 213 may surround the side surface of the semiconductor chip pad 211, and any one of the upper surface and the lower surface of the semiconductor chip pad 211 may be exposed from the dielectric layer 213 in the vertical direction Z. According to some example embodiments, the uppermost first semiconductor chip 210_U among the plurality of first semiconductor chips 210 may not include the through electrode 215.

According to some example embodiments, the surface roughness of the upper surface of the uppermost first semiconductor chip 210_U may be greater than the surface roughness of the upper surface of each of the other first semiconductor chips 210.

The first molding member 390 may be formed on the upper surface of the base chip 220 to surround the plurality of first semiconductor chips 210. For example, the first molding member 390 may surround the side surfaces of the plurality of first semiconductor chips 210 on the upper surface of the base chip 220.

The dummy chip 230 may be stacked on the uppermost first semiconductor chip 210_U in the vertical direction Z. The dummy chip 230 may be stacked on the uppermost first semiconductor chip 210_U through the adhesive layer 235.

According to some example embodiments, a laser drilling process may be performed on an area on the upper surface of the first molding member 390, which does not overlap the dummy chip 230 in the vertical direction Z.

The upper surface 390_US (see FIG. 4) of the first molding member 390, which does not overlap the dummy chip 230 in the vertical direction Z, may have a bumpy shape. The lower surface of the second molding member 490 on the upper surface 390_US (see FIG. 4) of the first molding member 390 may have a bumpy shape. In some example embodiments, no empty spaces may be provided between the upper surface 390_US (see FIG. 4) of the first molding member 390 and the lower surface of the second molding member 490.

According to some example embodiments, the area on the upper surface of the first molding member 390, which does not overlap the dummy chip 230 in the vertical direction Z, may include the modified area A. The modified area A may be located on the surface and in the inside of the area on the upper surface of the first molding member 390, which does not overlap the dummy chip 230 in the vertical direction Z. According to some example embodiments, the modified area A may be continuously formed up to a certain depth from the surface of the area on the upper surface of the first molding member 390, which does not overlap the dummy chip 230 in the vertical direction Z. According to some example embodiments, the density of the modified area A may be lower than the density of a lower area of the first molding member 390.

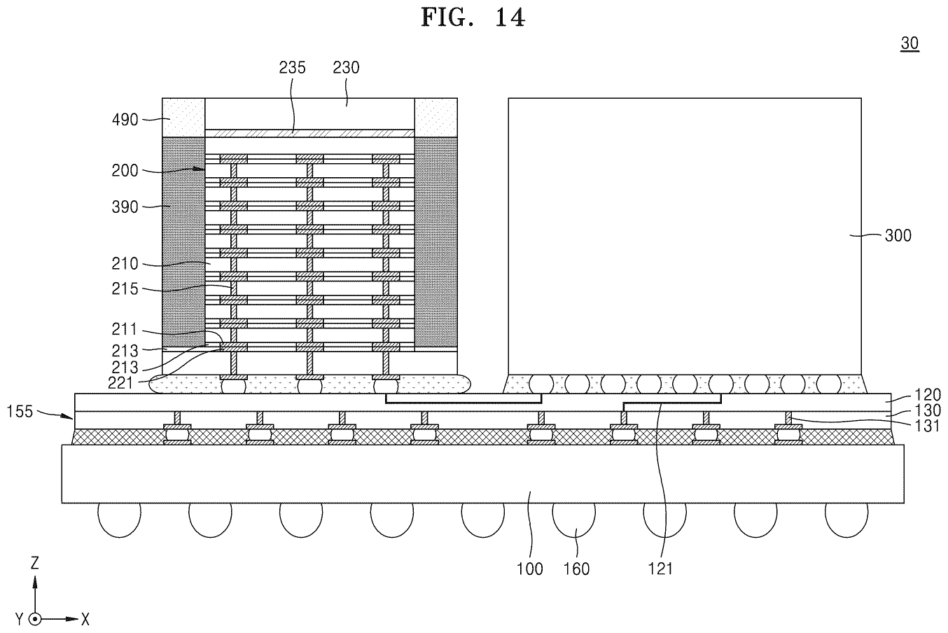

FIG. 14 is a cross-sectional view schematically illustrating a semiconductor package 30 according to some example embodiments. Hereinafter, the description made with reference to FIGS. 1 to 13 is not repeated, and differences from the description are mainly described.

Referring to FIG. 14, the semiconductor package 30 may include the first substrate 100, an interposer 155, the chip-stacked structure 200, and a second semiconductor chip 300. The first substrate 100 may be a substrate on which the chip-stacked structure 200 and the second semiconductor chip 300 are mounted. The external connection terminal 160 may be disposed on the lower surface of the first substrate 100 and electrically connected to the first substrate 100 via a pad formed on the lower surface of the first substrate 100.

The interposer 155 may include an interposer substrate 130, a wiring layer 120, and a through electrode 131. The interposer 155 may be disposed such that the interposer substrate 130 faces the first substrate 100. According to some example embodiments, the interposer substrate 130 may be formed based on Si. The through electrode 131 may pass through the interposer substrate 130 in the vertical direction Z. The through electrode 131 may be electrically connected to the first substrate 100 via a pad and a bump formed on the lower surface of the interposer substrate 130. The wiring layer 120 may include a wiring pattern 121. The wiring pattern 121 may electrically connect the chip-stacked structure 200 and the second semiconductor chip 300 to each other or electrically connect between the chip-stacked structure 200 and the through electrode 131 and between the second semiconductor chip 300 and the through electrode 131.

The chip-stacked structure 200 may include the base chip 220, the first semiconductor chip 210, the adhesive layer 235, and the dummy chip 230. The base chip 220 may be the lowermost chip in the chip-stacked structure 200. The through electrode 225 passing through the base chip 220 in the vertical direction Z may be located inside the base chip 220. The first semiconductor chip 210 may be stacked on the base chip 220 in the vertical direction Z. The base chip pad 221 and the dielectric layer 223 may be on the upper surface of the base chip 220. The dielectric layer 223 may surround the base chip pad 221. The dielectric layer 223 may surround the side surface of the base chip pad 221. The upper surface of the base chip pad 221 may be exposed upward from the dielectric layer 223 in the vertical direction Z. According to some example embodiments, a plurality of first semiconductor chips 210 may be provided. The plurality of first semiconductor chips 210 may be stacked in the vertical direction Z by direct bonding.

According to some example embodiments, the first semiconductor chip 210 may include the semiconductor chip pad 211, the dielectric layer 213, and the through electrode 215. The semiconductor chip pad 211 may be provided on each of the upper surface and the lower surface of the first semiconductor chip 210. The dielectric layer 213 may surround the semiconductor chip pad 211 on each of the upper surface and the lower surface of the first semiconductor chip 210. In some example embodiments, the dielectric layer 213 may surround the side surface of the semiconductor chip pad 211, and any one of the upper surface and the lower surface of the semiconductor chip pad 211 may be exposed from the dielectric layer 213 in the vertical direction Z. According to some example embodiments, the uppermost first semiconductor chip 210_U (see FIG. 13) among the plurality of first semiconductor chips 210 may not include the through electrode 215.

According to some example embodiments, the surface roughness of the upper surface of the uppermost first semiconductor chip 210_U may be greater than the surface roughness of the upper surface of each of the other first semiconductor chips 210.

The first molding member 390 may be formed on the upper surface of the base chip 220 to surround the plurality of first semiconductor chips 210. For example, the first molding member 390 may surround the side surfaces of the plurality of first semiconductor chips 210 on the upper surface of the base chip 220.

The dummy chip 230 may be stacked on the uppermost first semiconductor chip 210_U in the vertical direction Z. The dummy chip 230 may be stacked on the uppermost first semiconductor chip 210_U through the adhesive layer 235.

According to some example embodiments, a laser drilling process may be performed on an area on the upper surface of the first molding member 390, which does not overlap the dummy chip 230 in the vertical direction Z.

The upper surface 390_US (see FIG. 4) of the first molding member 390, which does not overlap the dummy chip 230 in the vertical direction Z, may have a bumpy shape. The lower surface of the second molding member 490 on the upper surface 390_US (see FIG. 4) of the first molding member 390 may have a bumpy shape. In some example embodiments, no empty spaces may be provided between the upper surface 390_US (see FIG. 4) of the first molding member 390 and the lower surface of the second molding member 490.

According to some example embodiments, the area on the upper surface of the first molding member 390, which does not overlap the dummy chip 230 in the vertical direction Z, may include the modified area A. The modified area A may be located on the surface and in the inside of the area on the upper surface of the first molding member 390, which does not overlap the dummy chip 230 in the vertical direction Z. According to some example embodiments, the modified area A may be continuously formed up to a certain depth from the surface of the area on the upper surface of the first molding member 390, which does not overlap the dummy chip 230 in the vertical direction Z. According to some example embodiments, the density of the modified area A may be lower than the density of a lower area of the first molding member 390.

The second semiconductor chip 300 may be mounted on the interposer 155. The second semiconductor chip 300 may be spaced apart from the chip-stacked structure 200 in the horizontal direction. The second semiconductor chip 300 may include a logic chip. The logic chip may be a microprocessor, such as a CPU, a GPU, or an AP, an analog device, or a digital signal processor.

While the inventive concepts has been particularly shown and described with reference to some example embodiments thereof, it will be understood that various changes in form and details may be made therein without departing from the spirit and scope of the following claims.

What is claimed is:

1. A semiconductor package comprising:
a base chip;
a plurality of first semiconductor chips sequentially stacked on the base chip in a vertical direction;
a first molding member on the base chip, the first molding member surrounding side surfaces of the plurality of first semiconductor chips;
an adhesive layer on an uppermost first semiconductor chip from among the plurality of first semiconductor chips;
a dummy chip on the adhesive layer; and
a second molding member on the first molding member, the second molding member surrounding respective side surfaces of the adhesive layer and the dummy chip.

2. The semiconductor package of claim 1, wherein an upper surface of the first molding member is coplanar with an upper surface of the uppermost first semiconductor chip.

3. The semiconductor package of claim 1, wherein
an area on an upper surface of the first molding member, which does not overlap the dummy chip in the vertical direction, is rougher than a lower surface of the first molding member.

4. The semiconductor package of claim 1, wherein an area on an upper surface of the first molding member, which does not overlap the dummy chip in the vertical direction, includes a modified area.

5. The semiconductor package of claim 4, wherein a density of the modified area is lower than a density of an area of the first molding member other than the modified area in the first molding member.

6. The semiconductor package of claim 1, wherein
the base chip includes a base chip pad and a first dielectric layer on the base chip, and the first dielectric layer surrounds a side surface of the base chip pad,
a lowermost first semiconductor chip from among the plurality of first semiconductor chips includes a semiconductor chip pad and a second dielectric layer on a lower surface of the lowermost first semiconductor chip, and the second dielectric layer surrounds a side surface of the semiconductor chip pad, and
the semiconductor chip pad contacts the base chip pad in the vertical direction, and the first dielectric layer contacts the second dielectric layer in the vertical direction.

7. The semiconductor package of claim 1, wherein a thermal expansion coefficient of the first molding member is different than a thermal expansion coefficient of the second molding member.

8. The semiconductor package of claim 1, wherein
a thickness in the vertical direction of the uppermost first semiconductor chip is greater than a thickness in the vertical direction of each of other first semiconductor chips from among the plurality of first semiconductor chips.

9. The semiconductor package of claim 1, wherein a footprint of the adhesive layer is larger than a footprint of the uppermost first semiconductor chip.

10. The semiconductor package of claim 1, wherein
a thickness in the vertical direction of the uppermost first semiconductor chip is a same thickness as a thickness in the vertical direction of each of other first semiconductor chips from among the plurality of first semiconductor chips.

11. A semiconductor package comprising:
a first substrate;
a base chip on the first substrate, the base chip including a base chip pad and a first dielectric layer on an upper surface of the base chip, and the first dielectric layer surrounding a side surface of the base chip pad;
a plurality of first semiconductor chips stacked on the base chip, each first semiconductor chip from among the plurality of first semiconductor chips including a semiconductor chip pad and a second dielectric layer on a lower surface of the first semiconductor chip, and the second dielectric layer surrounding a side surface of the semiconductor chip pad;
a first molding member on the base chip, the first molding member surrounding side surfaces of the plurality of first semiconductor chips;
an adhesive layer on an uppermost first semiconductor chip from among the plurality of first semiconductor chips;
a dummy chip on the adhesive layer; and
a second molding member on the first molding member, the second molding member surrounding respective side surfaces of the adhesive layer and the dummy chip,
wherein an area on an upper surface of the first molding member, which does not overlap the dummy chip in a vertical direction, includes a modified area, and
the semiconductor chip pad on the lower surface of a lowermost first semiconductor chip from among the plurality of first semiconductor chips contacts the base chip pad in the vertical direction, and the first dielectric layer on the upper surface of the base chip contacts the second dielectric layer on the lower surface of the lowermost first semiconductor chip in the vertical direction.

12. The semiconductor package of claim 11, further comprising:
an interposer between the first substrate and the base chip; and
a second semiconductor chip on the interposer, the second semiconductor chip being spaced apart from the base chip in a horizontal direction.

13. The semiconductor package of claim 11, wherein a density of the modified area is lower than a density of an area of the first molding member other than the modified area.

14. The semiconductor package of claim 11, wherein
the first molding member and the second molding member include different materials, and a thermal expansion coefficient of the first molding member is different than a thermal expansion coefficient of the second molding member.

15. The semiconductor package of claim 11, wherein
at least a portion of the adhesive layer overlaps the first molding member in the vertical direction, and at least a portion of the dummy chip overlaps the first molding member in the vertical direction.

16. The semiconductor package of claim 11, wherein
the area on the upper surface of the first molding member, which does not overlap the dummy chip in the vertical direction, is rougher than a lower surface of the first molding member.

17. The semiconductor package of claim 11, wherein an upper surface of the dummy chip is coplanar with an upper surface of the second molding member.

18. A semiconductor package comprising:
a first substrate;
an external connection bump on a lower surface of the first substrate;
a base chip on the first substrate, the base chip including a base chip pad and a first dielectric layer on an upper surface of the base chip, and the first dielectric layer surrounding a side surface of the base chip pad;
a plurality of first semiconductor chips stacked on the base chip, each first semiconductor chip from among the plurality of first semiconductor chips including a semiconductor chip pad and a second dielectric layer on a lower surface of the first semiconductor chip, and the second dielectric layer surrounding a side surface of the semiconductor chip pad;
a first molding member on the base chip, the first molding member surrounding side surfaces of the plurality of first semiconductor chips;
an adhesive layer on an uppermost first semiconductor chip from among the plurality of first semiconductor chips;
a dummy chip on the adhesive layer; and
a second molding member on the first molding member, the second molding member surrounding respective side surfaces of the adhesive layer and the dummy chip,
wherein an area on an upper surface of the first molding member, which does not overlap the dummy chip in a vertical direction, includes a modified area,
a footprint of the base chip is larger than a footprint of the plurality of first semiconductor chips,
the semiconductor chip pad on the lower surface of a lowermost first semiconductor chip from among the plurality of first semiconductor chips contacts the base chip pad in the vertical direction, the first dielectric layer on the upper surface of the base chip contacts the second dielectric layer on the lower surface of the lowermost first semiconductor chip in the vertical direction,
a density of the modified area is lower than a density of an area of the first molding member other than the modified area, and
the area on the upper surface of the first molding member, which does not overlap the dummy chip in the vertical direction, is rougher than a lower surface of the first molding member.

19. The semiconductor package of claim 18, wherein a thermal expansion coefficient of the first molding member is different than a thermal expansion coefficient of the second molding member.

20. The semiconductor package of claim 18, further comprising:
an interposer between the first substrate and the base chip; and
a second semiconductor chip on the interposer, the second semiconductor chip being spaced apart from the base chip in a horizontal direction.
